(19) United States
(12) Patent Application Publication
(10) Pub. No.: US 2026/0092968 A1
(43) Pub. Date: Apr. 2, 2026

(54) Interposer Assembly for System-Level Failure Analysis

(71) Applicant: Google LLC, Mountain View, CA (US)

(72) Inventors: Lesly Zaren Venturina Endrinal, San Diego, CA (US); Noor Jehan Binti Saujauddin, Pleasanton, CA (US); Dilbagh Singh, San Diego, CA (US); YuanChung Ho, San Diego, CA (US)

(73) Assignee: Google LLC, Mountain View, CA (US)

(21) Appl. No.: 19/412,315

(22) Filed: Dec. 8, 2025

Related U.S. Application Data
(60) Provisional application No. 63/921,633, filed on Nov. 20, 2025.

(51) Int. Cl. G01R 31/28; G01R 1/067; G01R 1/073

(52) U.S. Cl. CPC G01R 31/2886; G01R 1/06722; G01R 1/07342

(57) ABSTRACT

This document describes systems and techniques directed at an interposer assembly for system-level failure analysis. In aspects, the interposer assembly may include a main body with a central aperture configured to provide optical access to an exposed surface of a semiconductor device. A plurality of probe pins may be arranged on the main body surrounding the central aperture, the plurality of probe pins configured to make electrical contact with a corresponding plurality of fine-pitch contact pads on the semiconductor device. The interposer assembly may further include at least one connector disposed on the main body and physically offset from the central aperture configured to receive a memory module. Circuitry within the main body electrically couples the plurality of probe pins to the at least one connector. In such a configuration, accurate optical imaging and fault isolation analysis can be enabled while a semiconductor device is fully operational.

### CROSS-REFERENCE TO RELATED APPLICATION

This application claims the benefit of U.S. Provisional Patent Application Ser. No. 63/921,633 filed on Nov. 20, 2025, the disclosure of which is incorporated by reference herein in its entirety.

### SUMMARY

This document describes an interposer assembly for system-level failure analysis, such as for dynamic random-access memory (DRAM). In aspects, the interposer assembly includes a main body defining a central aperture configured to provide optical access to an exposed surface of a semiconductor device under test. A plurality of probe pins are arranged on the main body surrounding the aperture to make electrical contact with corresponding fine-pitch contact pads on the semiconductor device. The interposer also includes at least one connector, physically offset from the aperture, to receive a memory module. Internal circuitry electrically couples the probe pins to the connector, enabling simultaneous optical imaging and functional testing of the semiconductor device.

This Summary is provided to introduce simplified concepts of an interposer assembly for system-level failure analysis, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques directed at interposer assemblies for system-level failure analysis are described in this document with reference to the following drawings, in which the use of the same numbers in different instances may indicate similar features or components.

FIG. 1 illustrates a first example implementation of a DRAM interposer assembly for system-level failure analysis.

FIG. 2 illustrates a second example implementation of a DRAM interposer assembly for system-level failure analysis.

FIG. 3 illustrates a third example implementation of a DRAM interposer assembly for system-level failure analysis.

FIG. 4 illustrates a fourth example implementation of a DRAM interposer assembly for system-level failure analysis.

FIG. 5 illustrates an example environment in which aspects of a DRAM interposer assembly for system-level failure analysis can be implemented.

### DETAILED DESCRIPTION

### Overview

System-Level-Test (SLT) failure analysis (FA) of modern stacked-die packages, such as Integrated Fan-Out Package-on-Package (InFoPoP), presents a significant challenge. Performing SLT requires the system-on-chip (SoC) and its associated memory (e.g., DRAM, static RAM (SRAM), registers, embedded DRAM (eDRAM), read-only memory (ROM), magnetoresistive RAM (MRAM), resistive RAM (ReRAM), ferroelectric RAM (FeRAM)) to be electrically connected and functional. However, performing optical fault isolation (e.g., photon emission, laser stimulation) requires a clear optical line-of-sight to the backside of the SoC's silicon. In a conventional package, the stacked DRAM module physically blocks this optical access, preventing simultaneous SLT and optical FA.

SLT is a testing methodology used to validate a device in an environment that mimics its real-world application, often running actual software and functional test patterns. Failure analysis, and specifically optical fault isolation (OFI) using techniques like photon emission or laser stimulation, is a process for debugging and identifying the root cause of device failures. This problem is particularly acute in InFoPOP designs because of the small pitch of interconnects, specifically the small pitch of through-interposer vias (TIVs). Challenges arise when the stacked DRAM module physically blocks the optical line-of-sight needed for fault isolation techniques. To perform optical FA, the backside of the SoC silicon must be exposed, typically by polishing. Moreover, even if the DRAM were removed for optical access, many SLT tests could no longer run, as the SoC requires its associated memory to be electrically connected and functional to boot and execute test patterns.

To this end, this document describes systems and techniques directed to a DRAM interposer assembly for system-level failure analysis that allows optical access to an SoC while maintaining a functional SLT environment. In aspects, an apparatus may include a main body (e.g., an interposer) defining a central aperture, the central aperture configured to provide optical access to an exposed surface of a semiconductor device. A plurality of probe pins may be disposed on the main body and may be arranged in a pattern surrounding the central aperture, the plurality of probe pins configured to make electrical contact with a corresponding plurality of fine-pitch contact pads on the semiconductor device. The apparatus may further include at least one connector disposed on the main body and physically offset from the central aperture, the at least one connector configured to receive a memory module. In further aspects, the apparatus may include circuitry within the main body, the circuitry electrically coupling the plurality of probe pins to the at least one connector. In such a configuration, accurate optical imaging and fault isolation analysis can be enabled while a semiconductor device is fully operational.

The following discussion describes operating environments in which aspects of an interposer assembly for system-level failure analysis are described. It is to be understood that the subject of the appended claims is not necessarily limited to the specific features or methods described. Rather, the specific features and methods are disclosed as example implementations and reference is made to the operating environment by way of example only.

### Example Interposer Assembly

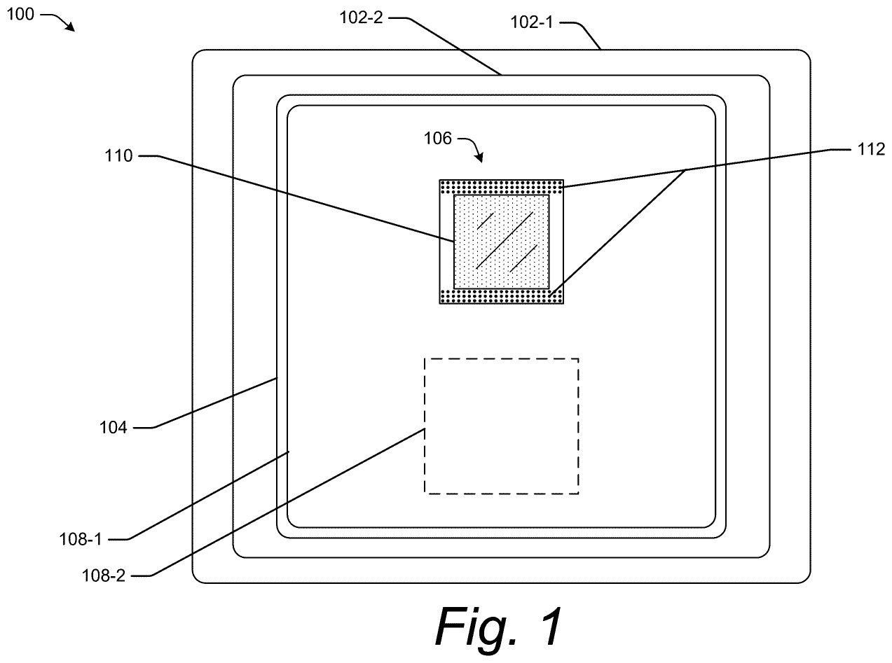

FIG. 1 illustrates a first example implementation 100 of a DRAM interposer assembly for system-level failure analysis. The example environment 100 includes a carrier board assembly 102 with an interposer 104 disposed on top of the carrier board assembly 102. The carrier board assembly 102 may include a printed circuit board (PCB) such as a coupon board, a device carrier board, or an SLT board used for mounting a device under test (DUT) for SLT and FA. More specifically, the carrier board assembly 102 may include a PCB socket 102-1 and a DUT PCB 102-2. The PCB socket 102-1 may be an SLT board used for mounting the DUT PCB 102-2 and a DUT. As illustrated in FIG. 1, the PCB socket 102-1 can provide the main base and test connections while the DUT PCB 102-2 is mounted on or above the PCB socket 102-1. The interposer 104, which functions as the main body of the apparatus (e.g., example environment 100), can be a specialized substrate containing internal circuitry designed to reroute electrical signals. The interposer 104 may define a central aperture 106, where the central aperture 106 is an opening or void through the main body of the interposer 104, specifically configured to provide a clear and unobstructed optical line-of-sight for analysis tools.

The example environment 100 further includes a DRAM assembly 108 mounted on top of the interposer 104 in a mounting area. The DRAM assembly 108 may include a DRAM PCB 108-1 and a DRAM module 108-2. The DRAM module 108-2 may be, for example, a dynamic random-access memory module such as a double data rate (DDR) module, or more specifically, a low-power DDR module (e.g., LPDDR4, LPDDR5) that can allow the DUT to run functional tests. The DRAM module 108-2 may be laterally adjacent to, or physically offset from, the central aperture 106 of the interposer 104. The DRAM PCB 108-1 may be electrically connected to the DRAM module 108-2.

The example environment 100 further includes a system-on-chip (SoC) die 110 located underneath the interposer 104 and visible within the central aperture 106. In aspects, the SoC die 110 is the primary semiconductor DUT and the component being analyzed for failures while actively running SLT software. The SoC die 110 may have a mechanically polished surface to expose one or more copper through-interposer vias (TIVs) 112 on the backside of the SoC die 110. The one or more copper TIVs 112 serve as the fine-pitch contact pads for the memory interface (e.g., DRAM module 108-2 interface). The one or more copper TIVs 112 are exposed in a frame-like pattern after the backside polishing process of the SoC die 110 and may have a very fine pitch (e.g., in a range of 200 to 270 micrometers). The exposed one or more copper TIVs 112 may be coated with electroless nickel immersion gold (ENIG) or electroless nickel electroless palladium immersion gold (ENEPIG) to prevent oxidation and ensure a strong electrical connection. The interposer 104 may be mounted around the SoC die 110 which places the DRAM module 108-2 on the side rather than the top, and this arrangement can allow for clearance for optical tools to analyze the backside of the SoC die 110.

In some implementations, the SoC die 110 is prepared for failure analysis through a process that includes mechanically polishing the SoC die 110 package on its backside to expose the silicon surface of the SoC die 110. The polishing may expose the one or more copper TIVs 112 in a frame-like pattern. The one or more copper TIVs 112 can be fine-pitch contact pads for interfacing with a memory module (e.g., the DRAM module 108-2). As illustrated in FIG. 1, the interposer 104 has a mounting area in which the DRAM module 108-2 is physically offset or laterally adjacent to the central aperture 106, which moves the DRAM module 108-2 out of the optical path of the SoC die 110.

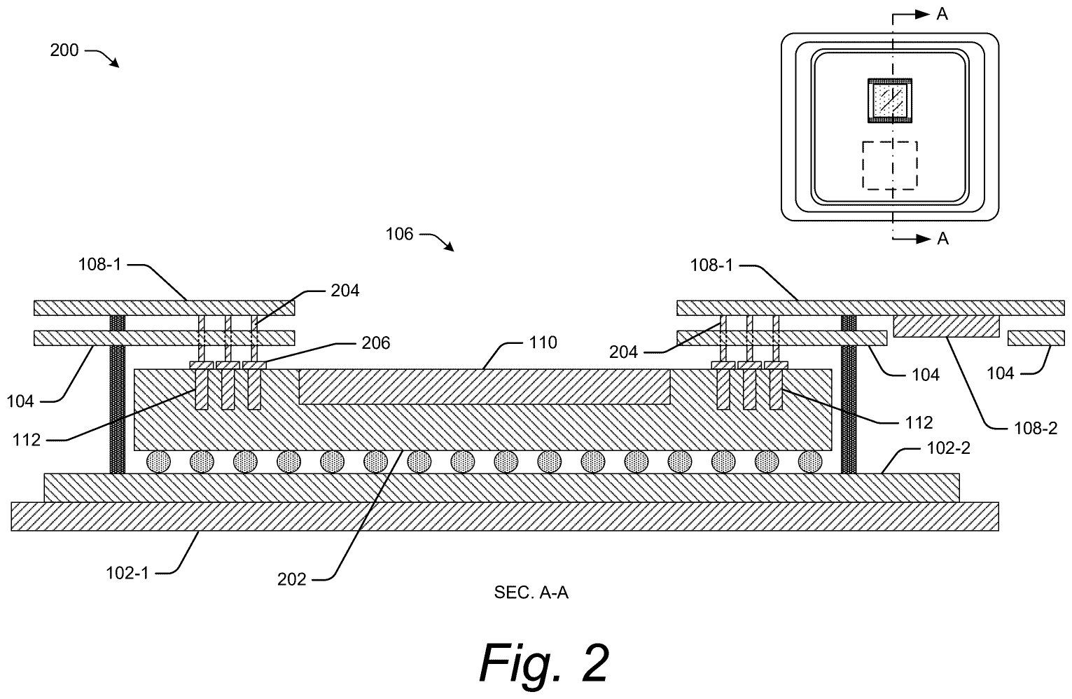

FIG. 2 illustrates a second example implementation 200 of a DRAM interposer assembly for system-level failure analysis. As illustrated, in cross-sectional view A-A of the assembly of FIG. 1, the SoC die 110 of FIG. 1 is mounted on the carrier board assembly 102 (e.g., the PCB socket 102-1 and the DUT PCB 102-2) of FIG. 1 with the die side down. The SoC die 110 is part of an SoC package 202 that directly interfaces with the carrier board assembly 102 through a solder connection. In some examples, the SoC package 202 can be screwed down to the carrier board assembly 102. The SoC package 202 may be the DUT assembly, which can be a complex package type such as an InFoPOP, a 2.5D package, or other multi-chip modules (MCMs) where the SoC die 110 is accessible from the backside after preparation. The interposer 104 of FIG. 1 is mounted above the carrier board assembly 102 and aligns with the SoC die 110 and the SoC package 202. The DUT PCB 102-2 may be connected to the interposer 104 and the DRAM PCB 108-1 of FIG. 1 with one or more screws or other mechanical connection. The central aperture 106 of FIG. 1 of the interposer 104 is the open space above the SoC die 110 and can allow for optical access from optical tools or imaging tools. The interposer 104 may also have a space for the DRAM module 108-2 of FIG. 1. The DRAM module 108-2 may be on an underside of the DRAM PCB 108-1 to allow for space for an optical tool to analyze the SoC die 110. Further, the DRAM module 108-2 may be on a right or left side of the DRAM PCB 108-1.

Cross-sectional view A-A also illustrates the one or more copper TIVs 112 of FIG. 1 interfacing with one or more probe pins 204 of the interposer 104. The one or more probe pins 204 are components of the interposer 104 and can be, for example, pogo pins, which are spring-loaded contacts. Other examples of the one or more probe pins 204 may include, but are not limited to, cantilever-style probes, vertical probes (e.g., cobra-style probes), or other micro-spring contacts, which are designed to make low-resistance contact with the one or more copper TIVs 112. Using the one or more probe pins 204 instead of conventional elastomers may allow for easier connection to the fine-pitched one or more copper TIVs 112. For example, the one or more copper TIVs may have a pitch in a range of 200 to 270 micrometers, such as 210 micrometers.

To ensure a reliable connection to the interposer 104, the exposed one or more copper TIVs 112 of the SoC die 110 may be coated with a non-oxidizing and conductive material 206. For example, the coating may be electroless nickel immersion gold (ENIG) or electroless nickel electroless palladium immersion gold (ENEPIG), which can prevent the copper from oxidizing. The ENIG coating (e.g., the non-oxidizing and conductive material 206) and/or the ENEPIG coating (e.g., the non-oxidizing and conductive material 206) may also provide a stable surface for the one or more probe pins 204 to interface with the SoC die 110, the SoC package 202, and the one or more copper TIVs 112. The interposer 104 may also contain internal circuitry (not illustrated) that can electrically couple the one or more probe pins 204 to the DRAM assembly 108 of FIG. 1. The internal circuitry may be used to replicate the original metal layers and interconnects that were polished away from the SoC package 202.

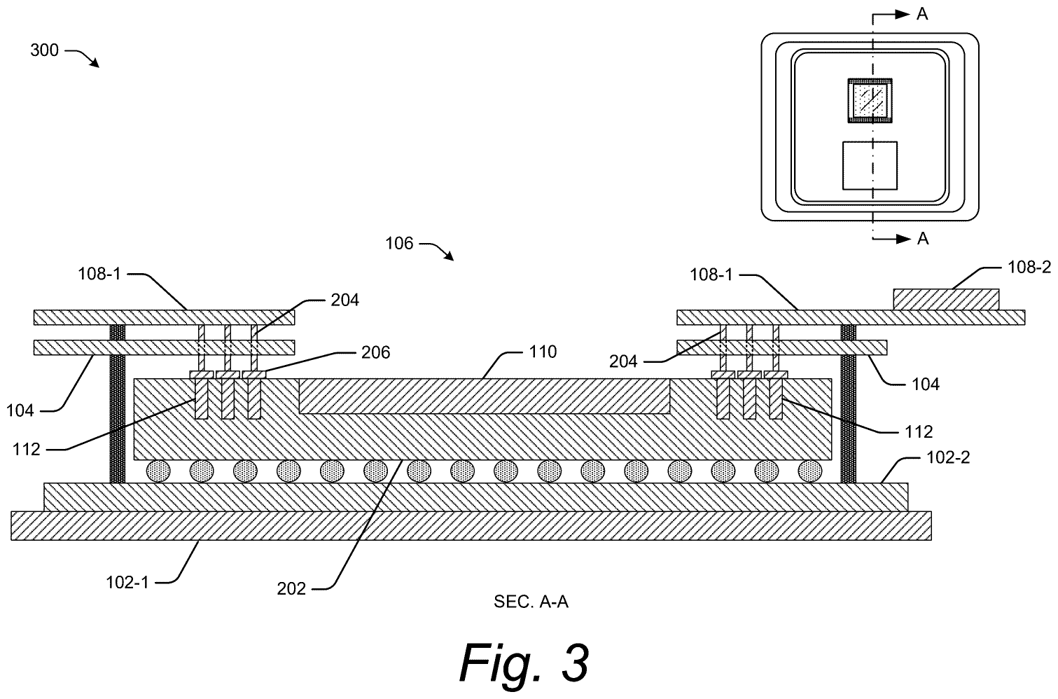

FIG. 3 illustrates a third example implementation 300 of a DRAM interposer assembly for system-level failure analysis. As illustrated, in cross-sectional view A-A of the assembly of FIG. 1, the SoC die 110 of FIG. 1 is mounted on the carrier board assembly 102 (e.g., the PCB socket 102-1 and the DUT PCB 102-2) of FIG. 1 with the die side down. The interposer 104 of FIG. 1 is mounted above the carrier board assembly 102 and aligns with the SoC die 110 and the SoC package 202. The DUT PCB 102-2 may be connected to the interposer 104 and the DRAM PCB 108-1 of FIG. 1 with one or more screws or other mechanical connection. The central aperture 106 of FIG. 1 of the interposer 104 is the open space above the SoC die 110 and can allow for optical access from optical tools or imaging tools. In example implementation 300, the DRAM module 108-2 of FIG. 1 may be on an upside of the DRAM PCB 108-1. Further, the DRAM module 108-2 may be on a right or left side of the DRAM PCB 108-1.

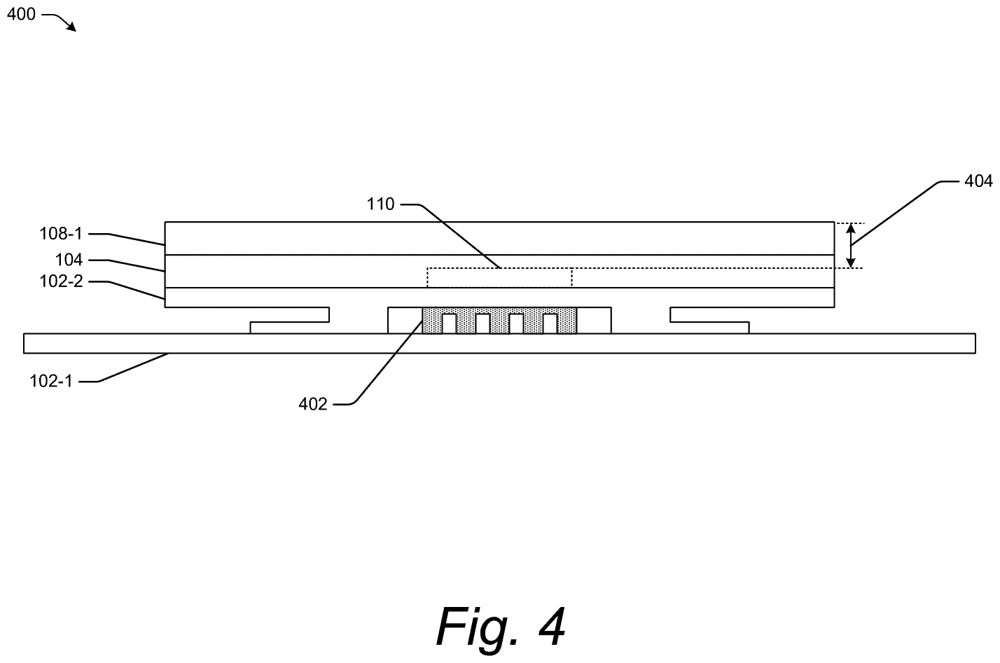

FIG. 4 illustrates a fourth example implementation 400 of a DRAM interposer assembly for system-level failure analysis. The example implementation 400 is a side view of the assembly (e.g., the first example implementation 100) of FIG. 1 and illustrates a total stack-up height of the assembly. The assembly includes the PCB socket 102-1 of FIG. 1, the DUT PCB 102-2 of FIG. 1, the interposer 104 of FIG. 1, the DRAM PCB 108-1 of FIG. 1, and the SoC die 110 of FIG. 1. The assembly is on the PCB socket 102-1 and can be screwed down through the DUT PCB 102-2. A heatsink 402 may be placed in thermal contact with the assembly, for example, on the bottom of the DUT PCB 102-2 and above the PCB socket 102-1. The heatsink 402 can provide thermal management for the SoC die 110, which may generate heat while actively running SLT software and test patterns (e.g., DDR tests). The heatsink 402 can dissipate this heat to ensure the SoC die 110 remains at a stable operating temperature, preventing thermal throttling that could invalidate the failure analysis results.

The assembly may further have a total stack-up height 404, which may be designed to be minimal. For example, the total stack-up height 404 is less than 10 millimeters. Specifically, the total stack-up height 404 may be 6 millimeters to allow for fitting under an optical tool or imaging analysis tool. The height constraint may be dictated by the working distance of the optical tools. An advanced optical fault isolation (OFI) system may have a limited working distance, so to ensure the FA lens can properly focus on the exposed silicon surface of the SoC die 110, the total stack-up height 404 of the entire assembly must fit within the limited working distance. One type of OFI system can be a specialized failure analysis tool that may use photon emission or laser-based techniques to pinpoint the precise location of electrical faults on the SoC die 110.

### Operating Environment

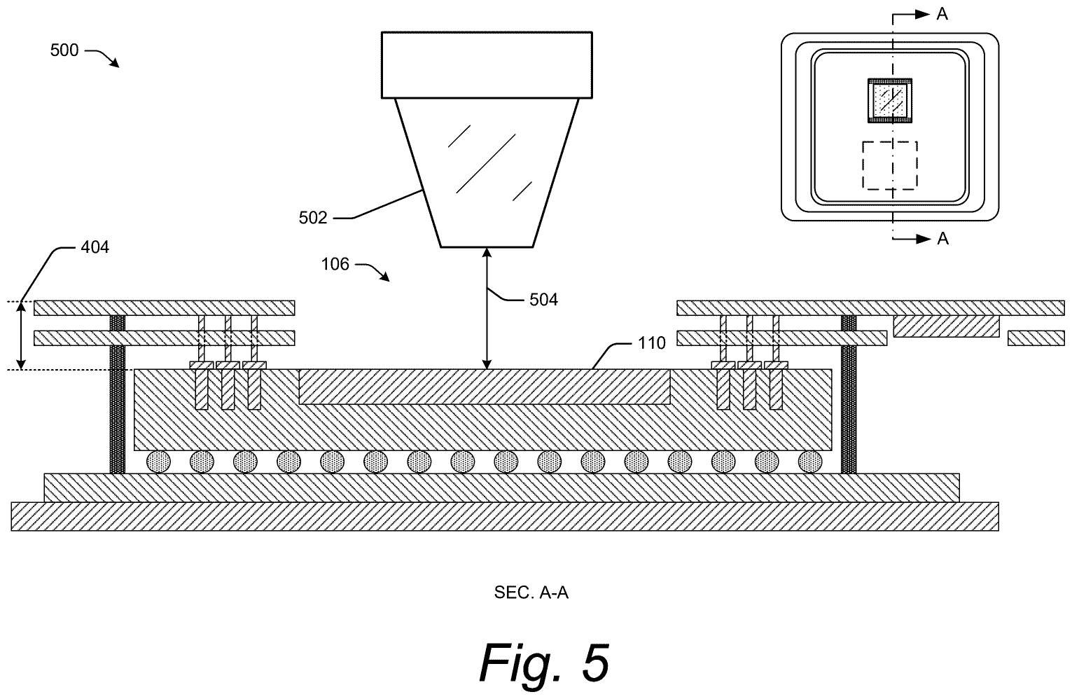

FIG. 5 illustrates an example operating environment 500 in which aspects of a DRAM interposer assembly for system-level failure analysis can be implemented. An optical tool 502 analyzes the SoC die 110 of FIG. 1 through the central aperture 106 of FIG. 1. As seen in FIG. 4, the total stack-up height 404 may be 6 millimeters to ensure proper and thorough optical imaging from the optical tool 502. The optical tool 502 may further have a working distance 504 of 10 millimeters or less, thus why the total stack-up height 404 may be less than 10 millimeters.

This configuration may enable SLT-based electrical fault isolation (EFI) by allowing the optical tool 502 to perform analysis while the SoC die 110 is actively running tests, such as DDR tests or other FA-compliant functional patterns. The optical tool 502 can be one of several types of optical fault isolation systems. For example, the optical tool 502 may be a photon emission analysis tool, which uses a highly sensitive lens to detect faint light emissions from transistors in an abnormal state. This can help to pinpoint sources of leakage or other defects. In another example, the optical tool 502 can be a thermal imaging tool, such as a mid-wave infrared (MWIR) lens, used for thermal mapping. This can allow users to visualize hotspots on the die that correspond to areas of high activity or electrical shorts. In a further example, the optical tool can be a dynamic laser stimulation (DLS) tool, which can scan the device with a laser to induce the changes in circuit behavior, allowing for the localization of timing-sensitive faults.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for an interposer assembly for system-level failure analysis have been described in language specific to certain features and/or methods, the subject of the appended claims is not necessarily limited to the specific features or methods described. Rather, the specific features and methods are disclosed as example implementations for an interposer assembly for system-level failure analysis.

What is claimed is:

1. An apparatus comprising:
a main body defining a central aperture, the central aperture configured to provide optical access to an exposed surface of a semiconductor device;
a plurality of probe pins disposed on the main body and arranged in a pattern surrounding the central aperture, the plurality of probe pins configured to make electrical contact with a corresponding plurality of fine-pitch contact pads on the semiconductor device;
at least one connector disposed on the main body and physically offset from the central aperture, the at least one connector configured to receive a memory module; and
circuitry within the main body, the circuitry electrically coupling the plurality of probe pins to the at least one connector.

2. The apparatus of claim 1, wherein the plurality of probe pins comprise pogo pins.

3. The apparatus of claim 1, wherein the plurality of fine-pitch contact pads are arranged in a pitch, the pitch being in a range of 200 to 270 micrometers.

4. The apparatus of claim 1, wherein the at least one connector is configured to receive a dynamic random-access memory (DRAM) module.

5. The apparatus of claim 1, wherein the apparatus is a height less than 10 millimeters.

6. The apparatus of claim 1, wherein the exposed surface of the semiconductor device is an exposed silicon surface of a system-on-chip (SoC).

7. The apparatus of claim 1, wherein:
the semiconductor device comprises an exposed silicon surface and the plurality of fine-pitch contact pads; and
the plurality of fine-pitch contact pads comprise copper through-interposer vias (TIVs).

8. The apparatus of claim 7, wherein the copper TIVs are coated with electroless nickel immersion gold (ENIG).

9. The apparatus of claim 7, wherein the copper TIVs are coated with electroless nickel electroless palladium immersion gold (ENEPIG).
